(19) United States
(12) Patent Application Publication
(10) Pub. No.: US 2017/0338127 A1
(43) Pub. Date: Nov. 23, 2017

(54) Methods for Forming Ceramic Substrates with Via Studs

(71) Applicant: Ananda H. Kumar, Fremont, CA (US)

(72) Inventor: Ananda H. Kumar, Fremont, CA (US)

(21) Appl. No.: 15/611,779

(22) Filed: Jun. 1, 2017

Related U.S. Application Data
(63) Continuation-in-part of application No. 14/684,427, filed on Apr. 12, 2015.
Application No. 14/684,427 is a continuation of application No. 12/558,490, filed on Sep. 11, 2009, now Pat. No. 9,006,028.
(60) Provisional application No. 61/096,315, filed on Sep. 12, 2008.

(51) Int. Cl. H01L 21/48; G01R 31/26; G01R 1/04; H05K 3/40; H05K 3/46; G01R 3/00; H05K 1/11

(52) U.S. Cl. CPC H01L 21/486; G01R 1/0491; G01R 31/2601; H01L 21/4807; H01L 21/4857; H01L 21/4867; H05K 3/4007; H01L 2924/00; H01L 2224/16225; H01L 2224/05655; H01L 2224/05573; H01L 2224/05571; H01L 2224/0557; H01L 2224/05568; H01L 2224/05124; H01L 2224/05008; H01L 2224/05001; G01R 3/00; H01L 2924/00014; H01L 2924/0002; H01L 2924/15312; H05K 1/111; H05K 3/4629; H05K 2203/308; H05K 2201/0367

(57) ABSTRACT

This document describes the fabrication and use of multilayer ceramic substrates, having one or more levels of internal thick film metal conductor patterns, wherein any or all of the metal vias intersecting one or both of the major surface planes of the substrates, extend out of the surface to be used for making flexible, temporary or permanent interconnections, to terminals of an electronic component. Such structures are useful for wafer probing, and for packaging, of the semiconductor devices.

This patent application is continuation and claims priority from U.S. utility patent application Ser. No. 12/558,490, filed on Sep. 11, 2009, entitle “Methods for Forming Ceramic Substrates with Via Studs”, which is incorporated herein by preference.

### BACKGROUND

The semiconductor technology has been following Moore's law relentlessly over the past two decades, with device densities now containing several million transistors. This has translated into ever increasing challenges in testing and packaging of these devices due to greatly increased need for input/output (I/O) terminal pads and decreased pad size and spacing. The leading-edge pad pitches and sizes are under 50 μm, a limiting value for wirebond technology. This has hastened the migration to area array solder bump, or flip chip bonding, which accommodates increased number I/O pads, significantly relaxing the pad size and density constraints for many memory devices. For ASICs and microprocessor type devices, number of area array I/O numbers, have routinely exceeded a thousand pads on a single device or chip, requiring ever smaller pad sizes and pitches, currently reaching 75 μm pads on 150 μm, respectively. The area array technology brings its own unique challenges in processing, package reliability, and testing. Added to these are the challenges to reduce the costs in device fabrication, testing, and packaging.

These challenges have been met though technological innovations in testing and packaging, materials, and structures. For packaging, the industry has developed low cost flip chip bonding substrates shown in FIG. 1.

Flip chip solder interconnection, also called Controlled Collapse Chip Connection or C4, for short, was first introduced by IBM more than 30 years ago. Kumar et. al. (U.S. Pat. No. 4,301,324) developed ceramic substrates of nearly same coefficient of thermal expansion, (CTE), as the device chip, allowing for very highly reliable solder connections. Today lower cost flip chip packages are made from plastic packages with high Coefficient of Thermal Expansion (CTE). In recent years the rest of the industry has also widely adopted this method of interconnection for connecting the chip directly to the board, inviting serious reliability problems involving fatigue failures in the solder joints. Adoption of flip chip, area array terminals for even low I/O devices has enabled packaging these devices on the wafer itself, thorough the so called Wafer Level Packaging, (WLP), methods, greatly reducing cost.

Reliability of flip chip solder joints to second level packages such as printed wiring boards, (PWB), is a serious concern, and becoming more so as the pad sizes decrease. One widely adopted mitigation strategy to enhance solder joint reliability is to use a polymer fill under the chip (so called “underfill”), entailing extra costs for process, materials, equipment, and yield loss. Another strategy, just coming into use, particularly for microprocessor device chips, is the so-called “copper bumps”, once again adding cost and complexity. This concern seriously jeopardizes the migration to smaller pad sizes pitches projected by the industry. While they add much cost and process complexity, these measures only improve fatigue life by less than a third.

Industry has also developed a versatile vertical probe technology using discrete metal wires, so-called COBRA probes, to test these area array chips. The increased numbers, densities, decreased sizes of area-array pads on device chip have brought about a commensurate need for new vertical probe technologies. Available vertical probe technologies are complex, expensive, and delicate. The introduction of micro-fabricated cantilever probes has met the challenges in testing the closely spaced, smaller wirebond pads. The so-called multi-DUT probes constructed from these have enabled greatly increased productivity though their ability to contact many dies simultaneously i.e. increased “test parallelism”.

One common method to form arrays of vertical probes is to attach metal wire extensions to the co-planar pads on the surface of substrates, same ones used for packaging the dies. The wire extensions are essentially truncated gold wire bonds formed on the gold plated substrate pads. The package provides the necessary electrical connections to the “wire probes”, routing them to conveniently spaced and located interconnection terminal pads used to join to the next level of interconnection, such as a printed wiring board, (PWB).This routing can be either to pads located on the same side of the central probe array, i.e. co-planar routing or, as is more common, to the opposite surface of the surface of the package. In this context, the package is often referred to as the “space transformer” because, invariably, the pad spacing of the terminal pads are much wider than that of the probe array. In this document the terms substrates and space transformers are used interchangeably. The space transformers are generally made of ceramic packages, often multi-layer ceramic packages with several levels of internal wiring, terminating on both the probe side and the “board side”, in co-planar pads that may be plated with nickel and gold. To form the probe array, soft gold wires are ultrasonically bonded to the pads, and specially shaped before truncating and planarizing the tops. The soft gold wires may be stiffened by coating with polymer, or with nickel alloys. Special tips and “electro-formed” arrays of cantilever beams of a suitable metal alloy are attached to the ends of the probes from wafer templates. Yet another method for forming probes involves building probe arrays on space transformers by lithographically patterned and plated thin films. Here, multiple plating steps are needed to obtain probe structures sufficiently tall, often as much as 0.5 to 2 mm, to overcome the global and local positional variations in the locations of the test pads on the wafers. Such micro-fabrication methods, can be carried out either right on the space transformer, or fabricated separately and transferred to the space transformer. The wire-bond probes and the micro fabricated probes are both delicate structures, which when bent or broken, are hard to repair or replace. Invariably, the probe cross-sections in these structures are significantly smaller than the diameters of the pads on the space transformer to which they are joined. Also they are adhered to the pads of the space transformer over-plating a hard metal on the base or joined with solder or braze. For these reasons, multi-Device Under Test (DUT) probes are fragile and, expensive.

In the prior art wafer probe structures discussed above, the process complexities, and the high fabrication costs, are the direct result of the need to elevate the probe tips significantly above the surface of the space transformer. This, in turn, is dictated by the requirement for the probe tips to bend and conform to the thousands of test pads on a wafer, compensating for the expected variations in probe heights, i.e. planarity, and variations in the wafer thickness, in pad sizes, locations, together adding up to 100-500 μm. Depending on the size of the probe array, the probe heights required to compensate for these factors can range from 25 μm, for a single DUT, area-array probe, to 500 μm for a multi-DUT probe. Some bending or compliance of the probe is also required to provide a level of “scrub” needed to break though oxide formed on the wafer terminals. Sophisticated probe array positioning and tilting schemes can decrease these heights, somewhat.

### SUMMARY

The present invention relates generally to methods and apparatuses for semiconductor chip packaging and testing, such as ceramic packages or ceramic probes for device testing. In an embodiment, the present invention discloses a contactor for semiconductor chips, and methods for fabricating the contactor. The present contactor comprises a plurality of via extensions, protruding from the top and bottom surfaces of the contactor. The via extensions have aspect ratio higher than 2×1, for example, to compensate for the height mis-matched between via extensions. In an aspect, the diameter of the via extensions is less than 500 microns, and preferably less than 100 microns. These via extensions are designed to be bonded to the bond pads of the semiconductor chips, for example, by soldering. Thus the size of the via extensions is preferably less than the bond pads” dimension. Soldering provides a potential alignment between the via extensions on the contactor and the bond pads on the semiconductor chips.

In an embodiment, the present contactor comprises a plurality of via extensions having contact tips fabricated from a semiconductor wafer. By fabricating the contact tips on a semiconductor wafer, the via extensions of the contactor can have the accuracy of semiconductor processing and the planarity of semiconductor wafer. The bonding between the via extensions and the contact tips can be accomplished by soldering, which can accommodate minor mis-alignment. In an aspect, a releasable layer is coated on a semiconductor wafer before the contact tips are formed, for example, by patterning and depositing. After bonding the via extensions to the contact tips, the releasable layer is released, freeing the contact tips from the semiconductor wafer.

In an embodiment, the present contactor comprises a plurality of via extensions having constricted solder bridge to allow ease of rework. The constricted solder bridge limits the amount of solder between the via extensions and the bond pads, thus providing a solid electrical connection between the contactor and the chip, and at the same time, providing a minimum soldering required to allow ease of removal. In an aspect, the constricted solder bridge comprises a coating, e.g., a polyimide coating, on the surrounding sides of the via extensions, preventing soldering to be attached to these sides. Thus the solder only attaches to the tip of the via extensions, or a portion of the top surface of the via extensions. In this case, after re-heating, the contactor and the chip can be separate with relative ease.

In an embodiment, the present invention discloses a chip package comprising a contactor having a plurality of via extensions solderingly bonded to the bond pads of one or more semiconductor chips. The use of soldering bonding allows the compensation for minor mis-alignment, both in lateral dimensions and in vertical dimension.

### BRIEF DESCRIPTION OF THE DRAWINGS

FIG. 1 illustrates prior art chip bonding.

FIG. 2 illustrates an exemplary chip size package to make permanent or temporary interconnections to devices with solder terminals.

FIG. 3 illustrates an exemplary LTCC process flow.

FIG. 4 illustrates an exemplary process of forming packages with via extensions.

FIG. 5 illustrates an exemplary full wafer flip chip, assembled on monolithic full wafer stud substrate.

FIG. 6 illustrates an exemplary wafer-level assembly of chip stud package.

FIG. 7A-7B illustrate an exemplary self-aligning flip-chip attached to wafer template, followed by wafer removal.

FIG. 8A illustrates an assembled probe package.

FIG. 8B illustrates a prior art probe assembly.

FIG. 9A-9B illustrate an exemplary process of forming studs with co-fired tips.

FIG. 10 illustrates a ceramic space transformer formed in-situ on a product wafer by aligning, attaching, and firing on a wafer size green laminate. The devices on the wafer can be tested at wafer level, or diced into die-sized packages for testing.

FIGS. 11 and 12A-12D illustrate an exemplary process flow for forming a contactor according to embodiments of the present invention.

FIGS. 13 and 14A-14D illustrate an exemplary process flow for forming a contactor with contact tips fabricated from a semiconductor wafer.

FIGS. 15 and 16A-16B illustrate an exemplary process flow for forming a contactor with constricted solder bridge.

FIGS. 17A-17C illustrate an exemplary rework process for bonding a contactor with constricted solder bridge to a temporary substrate.

FIG. 18 illustrates an exemplary bonding for un-constricted via extensions.

FIG. 19 illustrates an exemplary embodiment of the present integrated contactor on semiconductor wafer.

FIGS. 20A-20F and FIG. 21 illustrate a process for forming a contactor according to some embodiments.

FIGS. 22A-22C illustrate planarity variations for contactor probes according to some embodiments.

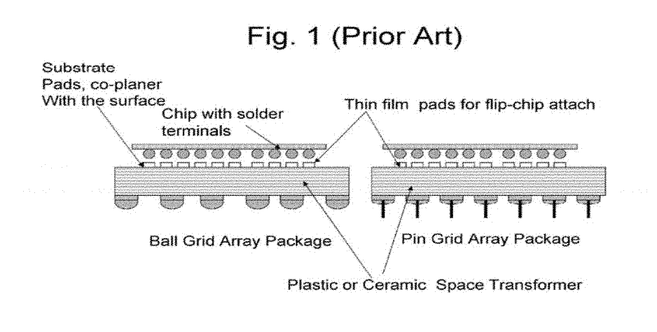

### DETAILED DESCRIPTION OF EMBODIMENTS OF THE INVENTION

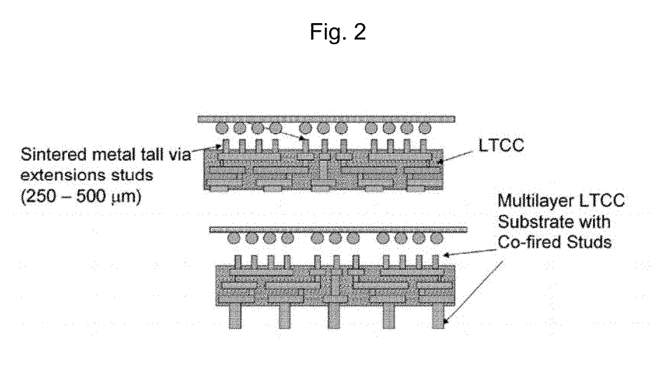

This invention in several of its embodiments addresses the twin challenges posed by today high density flip chip devices, viz. need for, (1) packaging technology that provides highly reliable solder joints in flip chip device packaging, and, (2)vertical probe arrays that are rugged, inexpensive, simple, and scalable. The common element for achieving these goals is a multilayer ceramic (MLC) substrate, having a coefficient of thermal expansion, CTE well matched to that of silicon, and having co-formed via extensions, or via studs illustrated in FIG. 2. The methods for fabricating these CTE-matched substrates also lends itself to fabricating them on product wafers, to obtaining great benefits to semiconductor manufacturers in wafer-level testing, burn in, and packaging.

In prior art, such co-formed or co-fired metal studs have been use, in one instance (D. Boss, A. Kumar et.al., U.S. Pat. No. 4,880,684), to translate the thin-film metal pads of the substrate thorough a soft polymer layer, upon which thin film pads are formed. The soft polymer layer shields the weak ceramic from cracking, due to the combined stresses of the thin film pad, and the solder joint to the chip terminals that sits on the pads. This entails high costs associated with coating a thick polymer layer over the studs, planarizing to expose the tops of the studs and thin film deposition and patterning of the terminal pads for solder attachment.

In another instance, (Itakagi, et.al. Intl. J. Microelectronics, pp. 46-51, 1997) similarly co-formed studs are used to make permanent, low stress, direct electrical connection to I/O pads of the chip, using soft conductive adhesives. The via studs are short, and the CTE of the substrate is not required to be matched to that of silicon. Such conductive adhesives have poor electrical conductivity, high contact resistance, and are not reliable in long term usage. Also, flip-chip conductive adhesive joining, unlike flip-chip solder joining, lacks the ability for self-alignment, necessitating precise die placement during joining. The structure of this prior art also requires additional reinforcement of the conductive adhesive joints in the form of a resin underfill layer, further adding cost and complexity.

The structures and methods of this invention are aimed at avoiding the complexity, cost, performance and reliability issues with conformed via stud structures, and of their use, in the above cited prior art methods. These via studs are merely extensions of thick film copper or silver vias from one or more layers of the substrate and are connected to Input/output (I/O), pads on the other side by redistribution lines. The via studs of this invention can be used for forming dense arrays of, flexible, low stress interconnections to silicon devices by flip chip soldering. The flexibility of the studs and the silicon CTE-matched ceramic in which they are rooted, make it possible to have high reliability, flip-chip solder interconnections.

These via studs, or hereinafter referred to simply also as studs, can also be used as flexible, elongated probes in wafer probing. By co-forming the studs during the substrate fabrication, the extra expense of wire attach, or micro-fabrication methods used for forming such elevations, are avoided here. The studs can be made sufficiently long, ranging from 25 μm to 1000 μm, longer if needed, to provide the necessary elevation to the probe tips to satisfy the planarity and compliance required for probe arrays to simultaneously contact all the test pads across a multiplicity of devices, across the whole wafer. The preferred range of the heights of the studs is from 50 μm to 250 μm. These studs, which are of the same diameter as the buried vias, will be quite rugged unlike the wire-bond formed probes of prior art. The probes of prior art, which are joined to the corresponding pads of the space transformer by weak gold-to-gold bonding, and require reinforcing in the form of over-plating, or solder coating the bond area. In contrast, the stud probes of this invention will be well anchored to the vias within the ceramic.

In the wafer probe application, these studs can be provided with special metal tips, using a silicon wafer as the template for the test pad tips, by flip-chip solder method that will naturally assure a high degree of co-planarity, and lateral positional accuracy for the probe tips. Here the self-aligning ability of flip chip solder interconnections is used to achieve this.

Other embodiments of this invention provides method for fabrication of these space transformers, and methods for using these for either testing, packaging, or for both. Such space transformers are also useful for diced single device chips, or for wafer-level testing and assembly.

Fabrication of Ceramic Substrates with Via-Studs:

Multilayer ceramic, (MLC), substrates have been in use for packaging single, and multiple chips for sometimes. The most common method for their fabrication uses “green tapes” for forming ceramic layers and thick film inks or pastes for forming conducting patterns in the layers, and layer-to-layer interconnections, commonly referred to as vias. The “green tape” is made by casting a paint-like slurry containing powders of a suitable ceramic and glass, with a polymeric binder dissolved in organic solvents, on a polymer film such as Mylar™ by the so called doctor blade method. Examples of polymeric binders are butadiene, or Butvar™, Poly-methyl methacrylate (PMMA).Mixtures of alcohols, such as Isopropyl alcohol, (IPA), and methanol, or ketones such as methyl iso-butyl-ketones (MIBK) are common solvents and vehicles for the slurry. After the solvents evaporate, the paper thin and rubbery green tape, now consisting ceramic and glass particles in a matrix of the polymeric binder, is cut or “blanked” to size with alignment holes at the comers. Via holes are punched at the required locations by automated mechanical methods using a programmable die and punch set, or by laser drilling. The conductor patterns are printed on to the green tape layers, using screens or stencils cut in metal foil, and the via holes are also filled with the same or similar conductor inks. The green tape layers are stacked in the required order and in good alignment between the layers, and laminated at a temperature of about 100° C., and pressures of between 250-1000 psi in a laminating press, to obtain a monolithic “green laminate”. The green laminate is then “sintered” by a programmed heating regimen, in suitable furnace ambient, first to completely remove the polymeric binder, and subsequently to sinter the ceramic powder, the metal particles in the conductor lines and vias, to obtain a monolithic sintered ceramic substrate with interconnected, buried and surface conductor patterns.

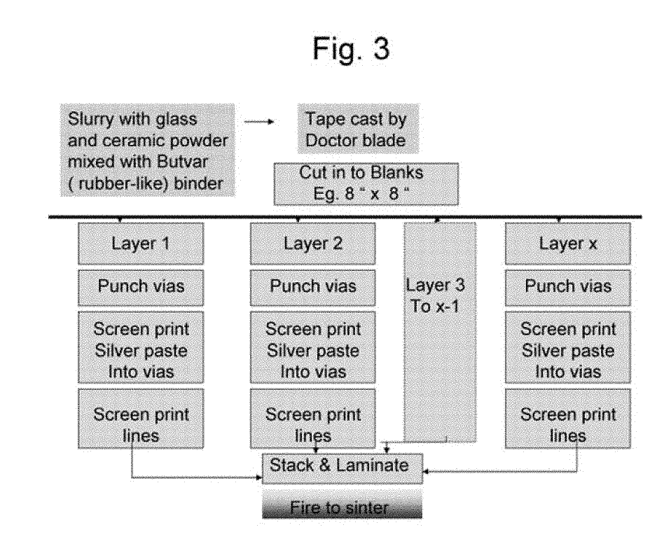

Commonly used ceramic powder in multilayer substrates is alumina, which would constitute from 80-96% by weight in the green tape with certain alkaline earth alumino-silicate glasses the remainder. When alumina is used as the ceramic, its high sintering temperatures requires the use of molybdenum or tungsten inks to form the conductors. The steps involved in the fabrication of such multilayer substrates are shown in FIG. 3. A good description of such multilayer substrates, including a detailed description of the steps in their fabrication, is given by in “Microelectronic Packaging” by A. R. Blodgett & D. R. Barbour, Scientific American, V 249 (1), pp 86-96 (1983), hereby incorporated by reference in its entirety.

Because of the high temperatures (>1400° C.) involved in the fabrication, this technology is commonly referred to as High Temperature Co-fired Ceramic, (HTTC) technology.

Certain special glass compositions whose powders sinter well between 800° C. and 1000° C., while simultaneously becoming crystalline, are useful in fabricating a lower temperature version of this technology in order to enable the incorporation highly conductive thick film metallurgy of copper, silver, or gold. Compositions consisting of physical mixtures of ceramic powders, usually alumina, with significant volume fraction of glasses that soften and flow at temperatures well below 1000° C. are also used for fabricating such multilayer structures. This technology for fabricating multilayer structures at these relatively lower temperatures to be compatible with thick film inks of silver, copper or gold, is commonly referred to as Low Temperature Co-fired Ceramic (LTCC) technology.

The total shrinkage of the green laminate on the way to full densification is about 50% by volume. In the prior art, a method for sintering LTCC substrates that completely suppresses the lateral (x, y) shrinkage of the substrates, forcing the entire shrinkage of the green laminate to take place in the z, or thickness, direction, involves using a green tape layer consisting of a refractory ceramic such as alumina, that is co-laminated to the top and bottom of the LTCC green laminate. We shall refer to the green tape layer containing the inert ceramic powder as the “contact sheet”. During sintering of the LTCC substrate, in the temperature range of 800° C.-1000° C., the ceramic powder in the topmost and bottommost contact sheet layers, does not densify and, thereby, prevents the lateral shrinkage of LTTC layers in between. This, in turn, forces the LTCC layers to densify totally in the z, or thickness direction. After the substrate is fully sintered and cooled, the inert contact layers, now reduced to a loose agglomeration of the inert ceramic powder, can be easily removed with a jet of water or air and the LTCC substrate is finished with plating or other operations for use as packages for semiconductor devices.

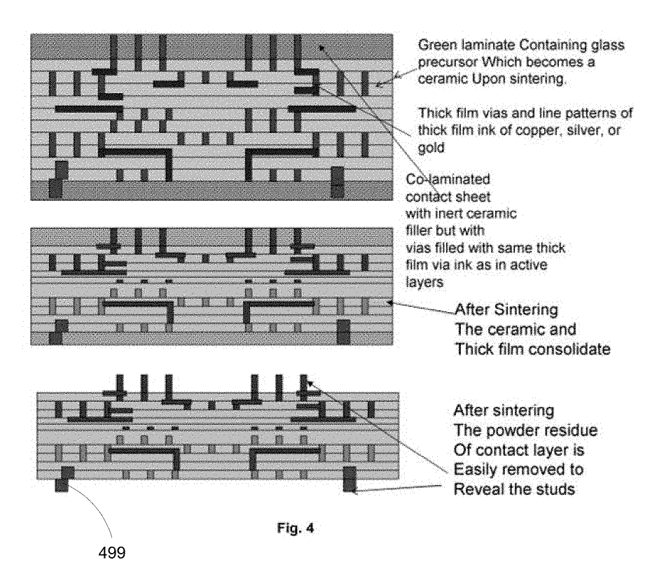

The via extensions are formed as follows: the inert contact layer for the top side is provided with the same filled via pattern as the topmost LTCC green tape layer, and co-laminated top most LTCC layer along with the rest of the green laminate. After the LTCC substrate is fully sintered, the inert ceramic layers are removed by blowing off with a jet of air or of water. This exposes the “via-extensions” or “studs” attached firmly to the vias emerging from topmost layer of the LTCC substrate. The height of the stud will generally end up to be about 50% of the thickness of the contact sheet in the green state, which typically ranges from 50 μm to 250 μm. The resulting metal studs will have a uniform height, which can range from 25 μm to 125 μm, depending on the thickness of the green sheet used for the contact layer. To obtain even taller studs, more than one green tape contact sheets with paste-filled vias, are co-laminated to the LTCC layers tape layers. Staggered stud structures 499 can be obtained by slightly displacing the vias in the contact sheets to a little extent. Even cantilever structures can be produced by using multiple contact sheets to a little extent (see FIG. 4). Even cantilever structures can be produced by using multiple contact sheet layers and printing the cantilever part of the structure on its surface and connected to the stud via. After the substrates are sintered the ceramic powder of the contact layer is washed off or blown-off without damaging the studs standing proud of the LTCC surface.

The same can be done to the bottom contact sheet of the green laminate to obtain via extensions there as well (FIG. 4). The inert contact sheet layers on the opposite side can also be utilized as above for forming studs. Generally the numbers of I/Os needed on the “board side” are significantly smaller than on the device side, thereby allowing for longer and larger diameter studs to be provided on this side. These studs would allow for easy electrical contact for testing and burning-in and very reliable permanent terminal for board attachment with reflow soldering methods. In all the application examples to follow, the backside terminals such as thick film or thin film metal pads, ball grid arrays, soldered or brazed pins, etc. are equally applicable. In the description of our invention that follows, we will interchangeably use substrates with studs on one side (device-side only) or on both, device side and the printed wiring board (PWB), or simply “board side”.

Using these methods, the substrate with via studs can be fabricated for device packaging. A wide choice of LTCC compositions are available commercially-available for fabrication of the LTCC substrates of this invention. In our preferred approach, a MgO—Al2O3—SiO2 glass composition, having MgO in the range of 15-28% by weight, Al2O3 in the range of 9-15% by weight, the remainder being silica, except for less than 2% of nucleating agents such as TiO2, ZrO2, P2O5, or B2O3.The glass powder of this composition fully densifies and crystallizes in the temperature range of 850° C. to 950° C., thereby co-sintering with thick film silver or copper pastes. Furthermore, the resulting ceramic has a dielectric constant of about 5, which is very good for packaging application. It has the additional benefit of having thermal expansion coefficient closely matched to that of silicon.

Monolithic Substrate for Packaging and Probing:

Space transformers with studs can be made either in a multi-up or multichip configuration. Multichip packages, can have shared circuitry, and are used as such for mounting several different types of chips to obtain a subsystem. In the multi-up configuration, a contiguous array of chip size space transformers having the same size and positional relationships as the devices on the corresponding product wafer, are formed for possible use as a wafer-scale contactor. Such a multi-up space transformer can also be diced to many chip-size space transformers, to be later re-assembled into multi-Device Under Test, multi-DUT, contactors, as described later. Each transformer in a multi-DUT space transformer is a distinct unit with no shared circuitry. Multi-up substrates form the basis for the embodiments of this invention.

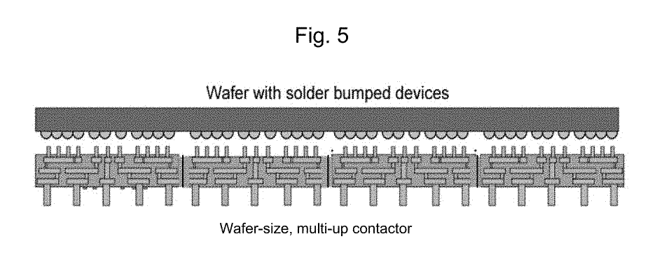

When the entire wafer is permanently assembled to the wafer-sized monolithic substrate as shown in FIG. 5, the I/O pads on the opposite side of the substrate, which are less numerous, larger, and much more widely spaced, can be accessed for electrical testing, and even burn in. It is obvious, that such a scheme for permanently attaching an entire device wafer to a substrate can only be useful when the device technology is stable, and device yields are high, and there is room for significant redundancies in the number of devices good when needed in the application. For full wafer flip chip process, the whole wafer is assembled on monolithic full wafer stud substrate, with the package outline fitting within the dicing lanes on the wafer.

When a substrate with studs is permanently attached to a semiconductor device for packaging by a flip chip solder method, the elongated studs provide considerable mechanical flexibility to the interconnection, and thereby help to enhance its fatigue life. This is analogous to the so-called copper bump technology that has been introduced by leading semiconductor makers to accomplish the same, at considerably lower cost than the latter.

The monolithic wafer-size, multi-up substrate assembly shown in FIG. 5, can also be used solely for performing wafer-scale testing, and burn in, if the solder attachment can be designed to be easily re-workable. One way to enable this is to limit the attachment area of the solder on top of the I/O studs on the package. A method for restricting the solder attach area is to place a polymer sheet with small holes drilled in it that correspond accurately to the I/O layouts of the devices across the entire wafer. The size of these holes are made to be just large enough to allow for easy solder penetration and coalescence of molten solder from both sides and, yet be small enough to easily and predictably separate the wafer from the package without significantly changing the solder balls on either. High temperature polyimide is an appropriate material for separation sheet in this use.

The probe assembly of FIG. 5 can also be used to make electrical connection to the test pads on a wafer though compliant z-axis connectors. Here, the normally non-conductive connector sheet will become locally conductive at points where the probes press on it against the wafer. Many other types of commercially available z-axis conductors can be used in the place of the Fujitsu material cited as an example above.

The monolithic wafer-scale-package with studs of FIG. 5 can also be used solely as a monolithic wafer-scale contactor for directly contacting the device terminals on the product wafer. Here the studs are brought only into physical contact with the terminals on the wafer, in a “wafer tester”.

Assembled Packages and Probe:

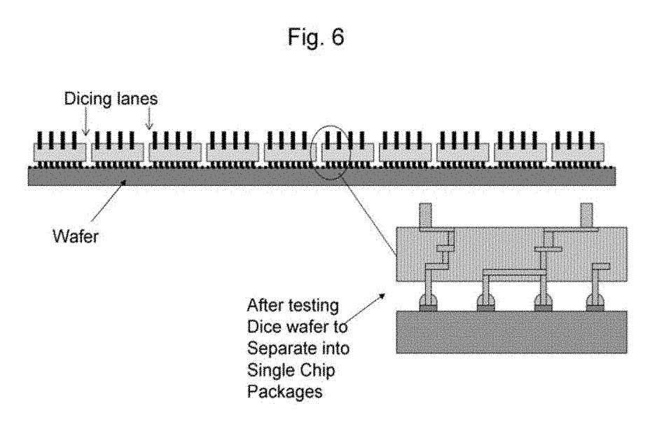

Another way to accomplish the wafer level assembly for testing, burn in and packaging, is to attach individual device-size space transformers of this invention, on to wafer by flip chip methods. The packages should be small enough to fit well within the dicing lines on the wafer. The self-aligning ability of such flip chip attachment enables accurate placement and assembly by using screen printed solder and metal stencils for packages to be dropped in, and reflow bonding of the packages over the entire wafer. When thus joined, the I/O terminals of the packages on the board side can be easily accessed for device testing and burn in, prior to dicing the packaged devices. Here, the individual device-size packages are tested, burning-in, diced and shipped, as packaged dies. Such a packaging and assembly scheme is illustrated in FIG. 6.

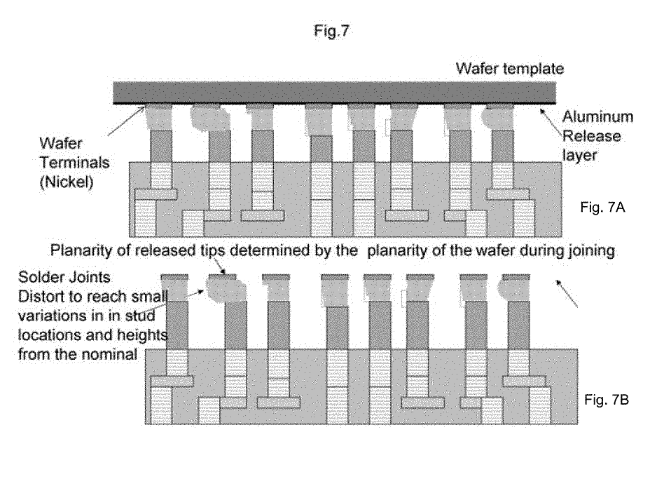

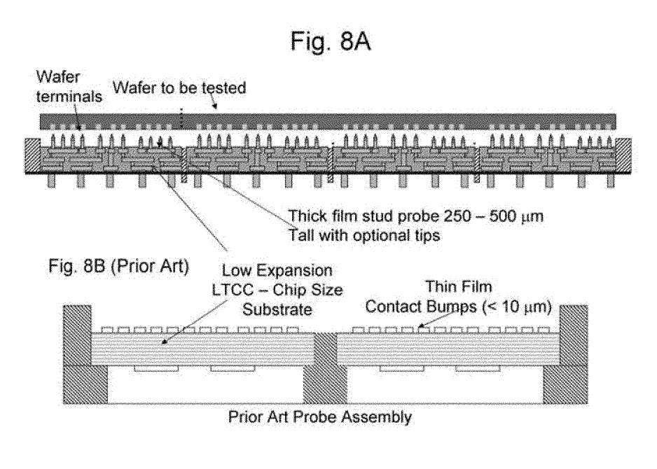

In a preferred method for forming an assembled wafer-scale-contactor, the single-chip size stud substrates are carefully assembled to obtain a multi-DUT wafer probe, using a wafer template having metal terminals identical to those on the product wafer, on a sacrificial metal layer. The terminal pads on the wafer template are fabricated on a sacrificial metal layer of aluminum. The wafer terminal pads will be at their correct nominal locations. However, the tips of the stud may be displaced from their correct lateral positions by small amounts. Here, the well known self-aligning characteristic of the flip-chip solder bonding comes to play and corrects small variations in x-y and z positional locations of the studs. The solder columns distort in shape to reach terminal pads on the wafer from slightly misaligned studs, as illustrated in FIG. 7A-7B. The planarity of the chip terminal pads is assured by holding the wafer flat against a flat wafer chuck during solder reflow. After such assembly, the space transformer array is captured by potting in suitable material, such as epoxy, before being released from the template by dissolving the sacrificial metal layer. Such an assembled multi-DUT probe is illustrated in FIG. 8A. Also shown for comparison in FIG. 8B is a prior art multi-DUT probe assembly, assembled using many individual single-chip ceramic packages, each smaller than the size of the devices, where the coplanar thin film metal pads, typically 10 μm or less in height, are used as the contacting probes. To achieve reliable contacting of the device test pads, these thin film pads should have extra-ordinary co-planarity. To achieve this, the single-chip packages are painstakingly assembled on to a specially constructed mechanical support and potted in place with a potting compound. The other shortcoming is the reliance on purely mechanical means to assure probe planarity.

In some embodiments, a contactor and a wafer-scale contactor can be fabricated using a semiconductor-base tips. The contactor body can be made with a ceramic substrate with probes formed by the via extensions from the substrate. The precision of the probe tips might not be accurate, e.g., it could be costly to make probe tips with the precision of semiconductor processing as required to probe terminal pads of semiconductor devices.

In some embodiments, the probe tips can be formed on a semiconductor wafer, and then bonded to the probes of the contactor. The lateral precision of the probe tips can be similar to that of the semiconductor devices, since the process can be similar, e.g., using semiconductor fabrication facility to process the probe tips. The vertical precision of the probe tips can also be similar to that of the semiconductor devices, since they both have the flatness of a semiconductor wafer.

The bonding of the probes to the semiconductor-base probe tips can be accomplished by solder or a solderable material. The solder or solderable material can flexed and stretch to accommodate small variations of the probe positions and heights.

The semiconductor tip precision can be particular advantageous for wafer-scale contactors, since multiple device-size contactors can be assembly side-by-side to form a wafer-scale size contactor. As discussed above, it can be time-consuming to assemble multiple device-size contactors, e.g., multi-DUT probe assembly, with the precision of semiconductor probing.

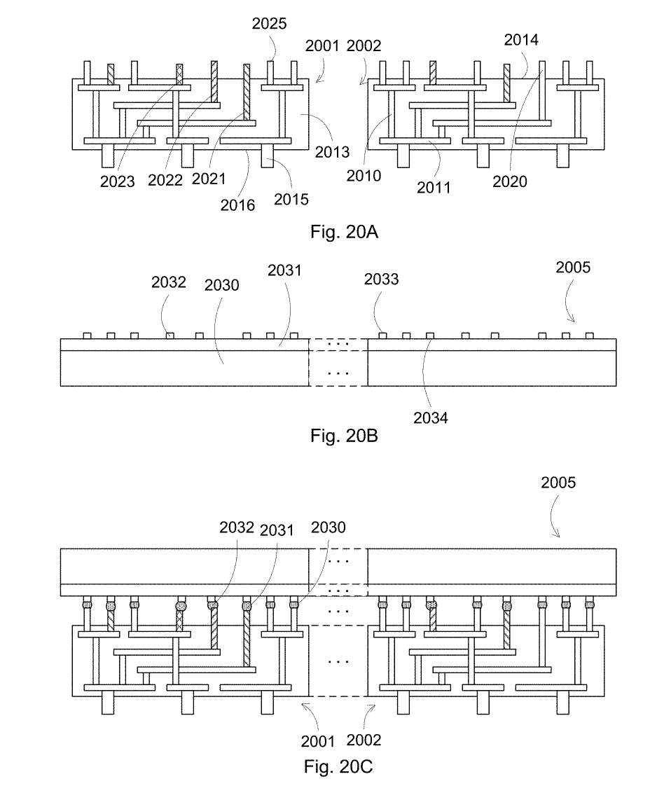

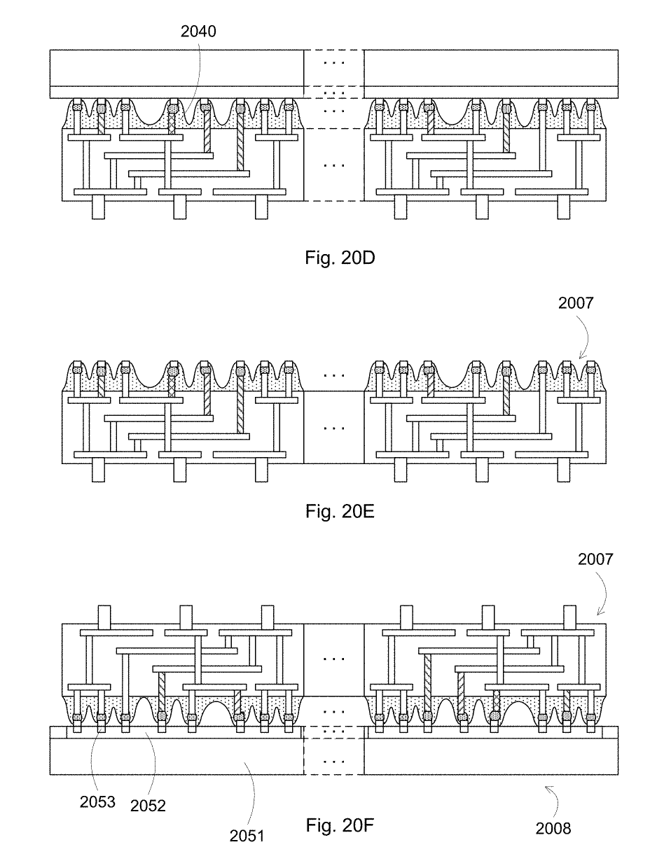

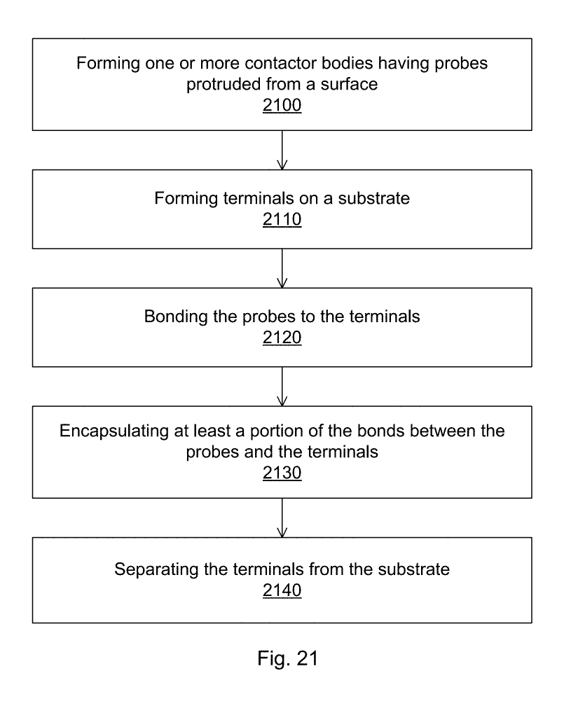

FIGS. 20A-20F and FIG. 21 illustrate a process for forming a contactor according to some embodiments.

Operation 2100 forms one or more contactor bodies having probes protruded from a surface. FIG. 20A shows two contactors 2001 and 2002, even though one or more than two contactors can be made. Each contactor body can include a substrate 2013, which has a surface 2014, e.g., an external surface or a surface exposed to outside ambient. The contactor body can include multiple probes 2020, e.g., via extensions, which can protrude from the surface 2014. The contactor body can optionally has probes 2015 protruded from an opposite surface 2016 of the substrate 2013. Connecting lines 2011 and connecting via 2010 can connect the probes 2020 and 2015.

There can be variations in positions of the probes, For example, probes 2021 and 2023 can be shorter than other probes. Probes 2022 and 2023 can be shifted laterally from correct nominal positions.

In some embodiments, the probes can have a planarity variation. The probes can be planar for probing terminal pads of a semiconductor device, meaning the probe tips 2025 are configured to be in a plane. Since a plane can be formed with 3 points, three probe tips can form a plane, e.g., the plane that contact the terminal pads. The other probe tips can be in the plane, or can be deviated from the plane. The deviation of the probe tip can form a planarity variation, e.g., the deviation of the probe tips from the plane that contact the terminal pads, or the plane formed by the terminal pads.

In some embodiments, the planarity variation can be characterized as a difference between at least a probe tip and the plane formed by at least three probes of the plurality of probes. The difference can be a difference of a particular probe tip. The difference can be a maximum difference of the probe tips of the contactor. The difference can be an average difference of the probe tips of the contactor.

Operation 2110 forms multiple terminals on a substrate. FIG. 20B shows a wafer-size terminal substrate 2005. The substrate 2005 can include a base substrate 2030, such as a semiconductor wafer. A releasable layer 2031 can be formed on the base substrate 2030. Multiple terminals 2032 can be formed on the releasable layer 2031. The releasable substrate can include any material that can be removed to separate the terminals 2032 from the base substrate 2030. For example, the base substrate 2030 can be a semiconductor wafer, e.g., made from silicon material. The terminals can include a nickel material. Thus the releasable layer can include an aluminum material, which can be dissolved without damaging the silicon wafer and the nickel terminals. The multiple terminals can be formed so that each terminal is separate from other terminals, e.g., after the releasable material is removed, each terminal does not contact, directly or indirectly, the other terminals. For example, there is only ambient environment between any two terminals. There is no solid material between any two terminals.

In some embodiments, the terminals can be formed by forming a pattern layer on the substrate. The pattern layer can include recesses. A conductive material can be deposited in the recesses, so that each recess can form a terminal. The recesses are separate from each other, so that the terminals, after the pattern layer is removed, form separate terminals. The pattern layer can act as a releasable layer, meaning the pattern layer can be removed to release the terminals.

In some embodiments, a releasable layer can be formed on the base substrate. A pattern can be formed on the releasable layer to form multiple separate recesses. And a conductive material can be formed in the recesses. Subsequently, the releasable layer can be removed to release the terminals.

In some embodiments, the terminals can be formed by depositing a pattern layer of a conductive material on a releasable layer. For example, a first layer can be formed on a substrate. The first layer can function as a releasable layer. A second layer of a conductive material can be deposited on the first layer. The second layer can be deposited as a pattern layer, for example, by using a mask to block unwanted areas from getting deposited. Alternatively, the second layer can be deposited as a blanket layer, and then being patterned to form multiple separate terminals.

In some embodiments, dimples can be formed on the substrate or on a releasable layer on the substrate. The dimples can include recesses with tips in the surface of the substrate. The dimples can be filled with a metal paste, and then the metal paste can be densified, for example, by a heat treatment.

In some embodiments, the terminals can have a planarity variation, which can be better than the planarity variation of the probes. The improved planarity variation, e.g., less planarity variation than the probes, can improve the planarity of the contactor, e.g., improving the contacting of the probes with the terminal pads of a device.

The terminals can be planar, meaning the surfaces of the terminals are configured to be in a plane, e.g., either the ambient surfaces 2033 facing the ambient environment, or the internal surface 2034 facing the substrate or the releasable layer. Since a plane can be formed with 3 points, three terminal surfaces can form a plane. The other terminal surfaces can be in the plane, or can be deviated from the plane. The deviation of the terminal surfaces can form a planarity variation.

In some embodiments, the planarity variation can be characterized as a difference between at least a terminal surface and the plane formed by at least three terminal surfaces. The difference can be a difference of a particular terminal surface. The difference can be a maximum difference of the terminal surfaces. The difference can be an average difference of the terminal surfaces.

In some embodiments, the planarity variation formed by the terminal surfaces (or by the terminals) can be less than the planarity variation formed by the probe tips (or by the probes).

Operation 2120 bonds the probes to the terminals. The probes can be bonded to the terminals by using solder or a solderable material. The solder or a solderable material can accommodate the difference in lateral positions and in vertical positions between the probes and the terminals. Thus after bonded, the probes can have the terminals as probe tips, with much improved planarity and lateral position accuracy. One contactor can be used to bond the probes to the terminals of a substrate. Alternatively, multiple contactors can be used to bond the probes of the multiple contactors to the terminals of a substrate.

FIG. 20C shows multiple contactors 2001 and 2002 assembled together, and then the probes of the multiple contactors can be bonded to the terminals of the substrate 2005. The bonding can use a solder or a solderable material, which can accommodate a variation between the probes and the terminals. For example, a solder 2030 can be formed between a probe with proper lateral positions and height. A solder 2031 can be formed between a probe with proper lateral positions but a difference in height. A solder 2032 can be formed between a probe with a difference in lateral positions and a proper height.

Operation 2130 encapsulates at least a portion of the bonds between the probes and the terminals. The bonds between the probes and the terminals can be of a solder material, thus can be susceptible to the ambient, such as temperature. Thus the bonds can be at least partially embedded in an encapsulating material, such as a resin or a polymer. In some embodiments, at least a portion of the terminals, the bonds between the probes to the terminals, and the probes can be encapsulated. FIG. 20D shows that the terminals, the bonds between the probes to the terminals, and the probes can be encapsulated with an encapsulating layer 2040. The encapsulating layer can leave surfaces of the terminals (e.g., the internal surface 2034 facing the substrate or the releasable layer), and a portion of the terminals next to the surfaces, exposed.

Operation 2140 separates the terminals from the substrate, for example, by removing the releasable layer between the terminals and the substrate. The separation process can also separate the terminals from each other, e.g., leaving each terminal not directly or indirectly touches another terminal. Since the terminals can be functioned as the probe tips, e.g., located at the tips of the probes, the terminals are separate from each other, e.g., there is no solid material between the terminals. FIG. 20E shows the contactor 2007 after the substrate is separated from the probes.

In some embodiments, the encapsulating process can be performed before the separation process. Alternatively, the encapsulating process can be performed after the separation process.

FIG. 20F shows the contactor 2007 contacting a wafer for testing devices. A wafer 2051 can be fabricated with multiple devices 2052, each with multiple terminal pads 2053. The probe tips, e.g., the terminals bonded to the tip of the probes, can contact the terminal pads for electrical testing.

In some embodiments, multiple device-size contactors can be assembled together, for example, into a size and shape of a wafer. Then the probes of the contactor assembly can be bonded to the terminals of a wafer size substrate. After the wafer size substrate is removed from the terminals, for example, by releasing a releasable layer between the terminals and the wafer-size substrate, a wafer-size contactor 2007 including multiple device-size contactors can be formed.

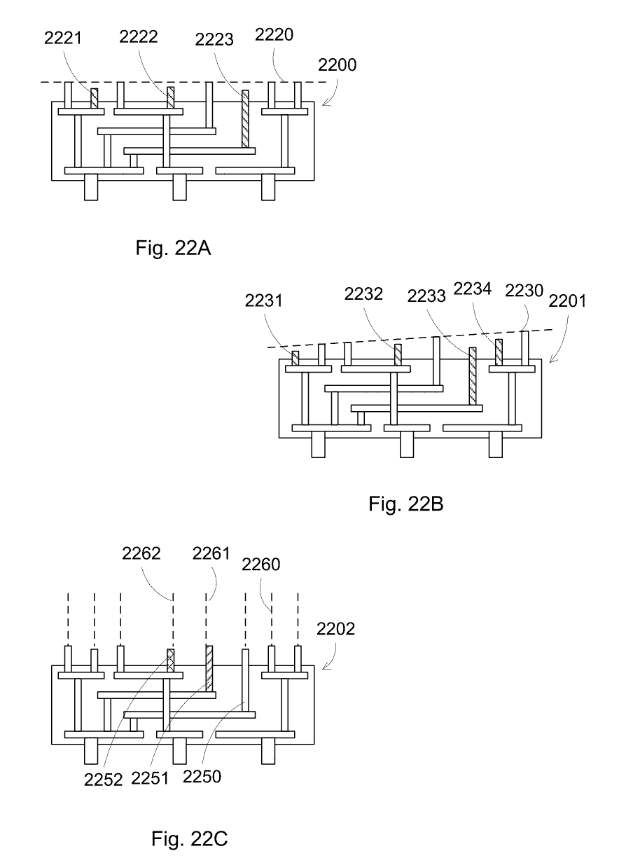

FIGS. 22A-22C illustrate variations for contactor probes according to some embodiments. FIG. 22A shows a planarity variation of the probes of a contactor 2200. Many probes can form a plane 2220 with some probes shorter. For example, probes 2221, 2222, and 2223 can be shorter, leaving a gap between the tips of the probes with the plane 2220. The plane 2220 can be the plane to contact the terminal pads of devices, e.g., if using the contactor without the terminal tips according to the present invention. Thus there can be no probes protruded above the plane 2220. The plane 2220 can be called contact plane, e.g., a plane formed by many probes without any probes protruded above the contact plane.

A planarity variation can be a difference between the plane 2220 and a probe not on the plane, e.g., a difference between the plane 2220 and one of the probes 2221, 2222, and 2223. A planarity variation can be a maximum difference between the plane 2220 and probes not on the plane, e.g., a maximum difference between the plane 2220 and the probes 2221, 2222, and 2223, e.g., the largest difference between plane 2220 and probe 2221, between plane 2220 and probe 2222, and between plane 2220 and probe 2223. A planarity variation can be an average difference between the plane 2220 and probes not on the plane, e.g., an average difference between the plane 2220 and the probes 2221, 2222, and 2223.

FIG. 22B shows a planarity variation of the probes of a contactor 2201. The contact plane 2230 can be tilted (as compared to a horizontal contact plane 2220 in FIG. 22A). Some probes can be shorter. For example, probes 2231, 2232, 2233, and 2234 can be shorter, leaving a gap between the tips of the probes with the plane 2230. The plane 2230 can be the plane to contact the terminal pads of devices, e.g., if using the contactor without the terminal tips according to the present invention. Thus the contact plane 2230 can be tilted.

A planarity variation can be a difference, e.g., a single difference, a maximum difference, or an average difference, between the plane 2230 and one or more probes not on the plane, e.g., a difference between the plane 2230 and one or more of the probes 2231, 2232, 2233, and 2234.

In some embodiments, the planarity variation of the probes can be higher than the planarity variation of the terminals. The terminals can be fabricated on a substrate, so the planarity variation of the terminals can be the flatness of the substrate. Using a semiconductor wafer, the flatness can be minimal, such as less than 40 μm bow for a 150 mm wafer. Thus using terminals fabricated on a highly planar substrate, such as a semiconductor wafer, the planarity variation for the contactor having terminals as probe tips can be minimal, e.g., similar to that of the substrate (e.g., the semiconductor wafer).

FIG. 22C shows a lateral position variation of the probes of a contactor 2202. The probes, such as probe 2250, can be at the correct lateral position 2260. Some probes can be deviated from the correct lateral positions. For example, probe 2251 can be displaced to the right from the correct lateral position 2261. Probe 2252 can be displaced to the left from the correct lateral position 2262.

A lateral variation can be a non-zero difference, e.g., a single difference, a maximum difference, or an average difference, between the correct lateral positions to the actual positions of the probes. For example, the difference for probe 2250 is zero, e.g., the probe 2250 is at the correct lateral position 2260. There are differences for probes 2251 and 2252, e.g., the probes 2251 and 2252 are not at their correct lateral positions.

In some embodiments, the lateral variation of the probes can be higher than the lateral variation of the terminals. The terminals can be fabricated on a semiconductor wafer using semiconductor processes, so the lateral variation of the terminals can be the lateral variation of the semiconductor facility. Thus using terminals fabricated on a semiconductor wafer using standard semiconductor processes, the lateral variation for the contactor having terminals as probe tips can be minimal, e.g., similar to that of the devices to be tested.

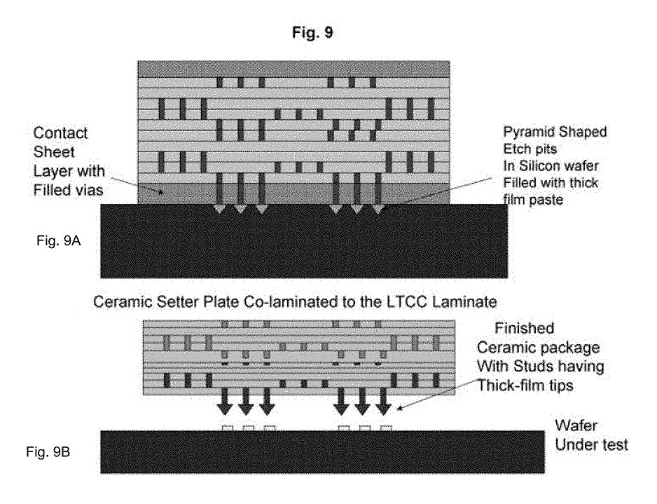

The fabrication of LTCC substrates with integral via studs, described previously, can also be extended to provide, co-fired, sintered tips, with the required positional accuracy, together with required tip shapes as follows. The green LTCC laminate with the top bottom inert contact layers containing vias filled with metal pastes that form the studs, are usually fired on ceramic setter tiles. Here, in this embodiment, the setter tile is replaced by a silicon wafer template provided with shaped dimple arrays at locations corresponding to the terminals of the device wafer to be tested. These dimples are filled with suitable metal paste, the same one used to form the stud, i.e. copper, silver, or gold. Next the green (i.e. unfired) LTCC laminate, with contact layer, is placed in good alignment between the stud locations and these tip arrays on the wafer template, using an alignment aligning fixture. The green laminate is then sintered, as usual, to densify the LTCC ceramic and the metal interconnects. During sintering, lateral shrinkage of the laminate is completely suppressed, and the entire densification is accommodated by the shrinkage in the thickness direction. During this process, the paste-filled dimples in the silicon wafer template also densify to form shaped tips, and attach themselves to ends of the studs in the inert tape layers. The sintered laminate is released, and the inert ceramic powders of the contact layers are removed by washing or blowing off. Since the wafer template does not shrink laterally during sintering, the locations of the tips are fixed. Also the flat wafer template assures both positional accuracy and co-planarity of the tips. The methods to form accurately shaped and sized dimples in the wafer template is by anisotropic etching though a resist pattern is well known in the art. This typically produces pyramid-shaped tips (FIG. 9A-9B).

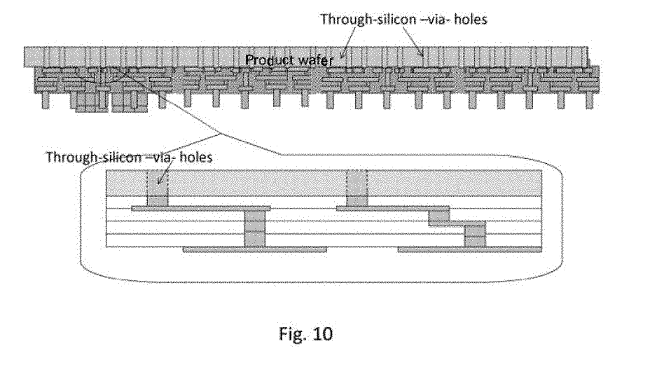

FIG. 10 illustrates a further embodiment of this invention. Here, the wafer template of the above example is replaced by a un-processed wafer, i.e. one without devices fabricated thereon. Here the un-processed product wafer is first provided with though-silicon-via holes to enable later electrical connection to device terminals to be fabricated subsequently on the wafer-side of ceramic-wafer composite. The green ceramic laminate with thick film silver metallization paste circuit pattern throughout, including silver paste-filled vias on both sides is prepared with a co-laminated contact sheet on the “board-side” only, is also prepared separately. The green laminate thus prepared is placed on the previously prepared un-processed wafer such that the vias filled with silver paste on the “device side” of the laminate are in good alignment with the corresponding though-silicon via holes, and pressed thereon at moderate temperature and pressure. The wafer-laminate assembly is then cured at the required high temperature to consolidate the ceramic dielectric and the silver conductor features. The contact sheet on one side and the solid wafer on the other, act to eliminate any lateral shrinkage in relatively thin laminates, thus preserving the location accuracy of the circuit features. During this consolidation, the ceramic dielectric strongly bonds to the oxidized surface of the silicon wafer forming in-effect, a silicon-on-insulator or SOI wafer with built-in through-silicon-via holes, and an integral ceramic interconnect structure. The SOI wafer is then used to fabricate desired semiconductor devices thereon, including through-silicon-via interconnections, to the silver pads on the integral package, by methods known to the industry. This scheme will provide a very economical means for wafer-level testing and packaging. To successfully accomplish this in-situ substrate fabrication, the starting glass in ceramic composition should densify and adhere well to the oxidized silicon surface, and posses a coefficient of thermal expansion well matched to that of silicon. MgO—Al2O3—SiO2 glasses cited earlier, have these attributes. This also accomplishes several major objectives of Intel Corporation so-called, “Bumpless Bonding Build-Up Laminate (BBUL)” structure (Towle and Wermer, U.S. Pat. No. 6,555,906), on a wafer-level, elegantly and economically.

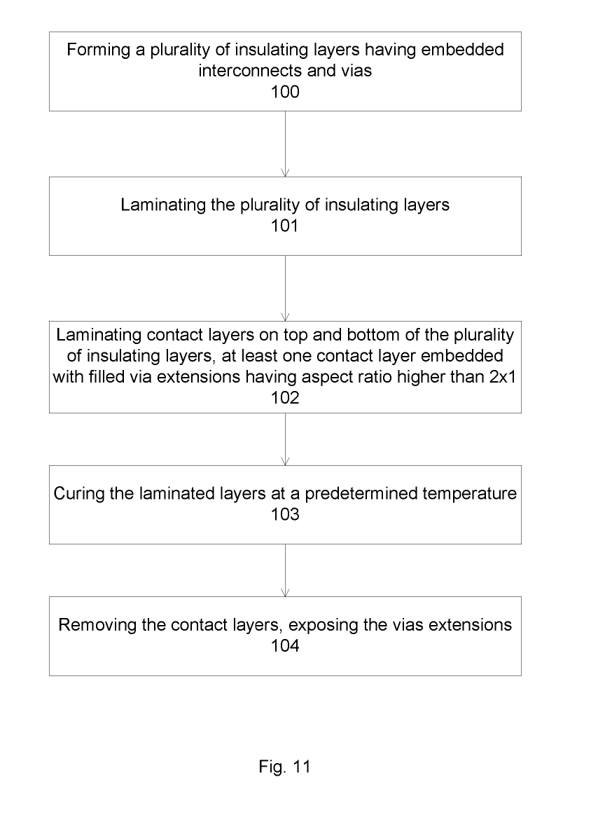

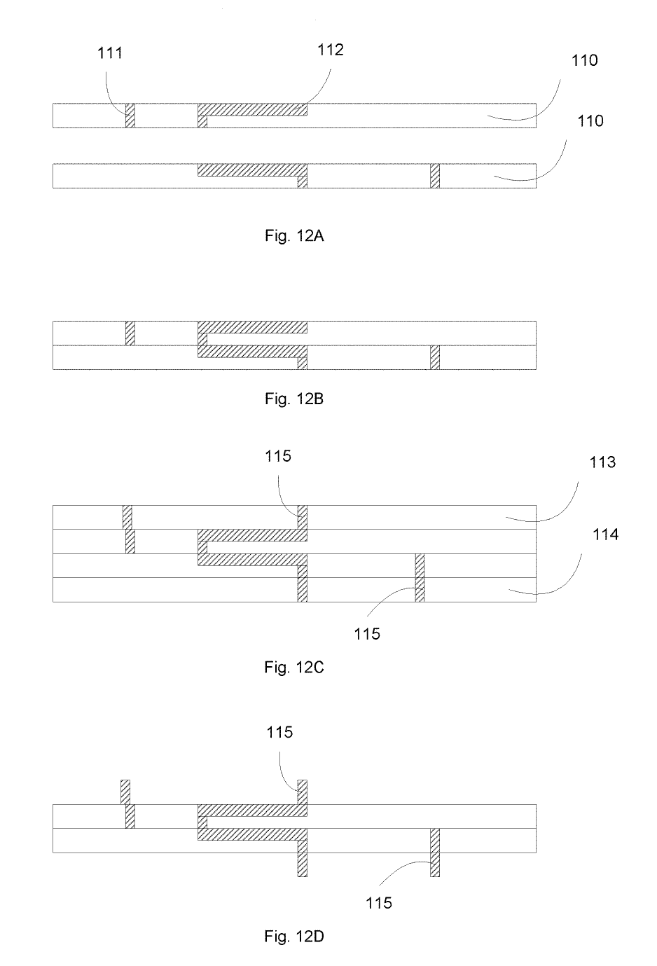

FIGS. 11 and 12A-12D illustrate an exemplary process flow for forming a contactor according to embodiments of the present invention. Operation 100 forms a plurality of insulating layers having embedded interconnects and vias (FIG. 12A). The insulating layers 110 can be ceramic green sheets, with conductive lines 112 for interconnects, and filled punched holes Ill for vias. Operation 101 laminates the plurality of insulating layers together with proper alignment (FIG. 12B). Operation 102 laminates a contact layer on top and a contact layer on the bottom of the plurality of insulating layers (FIG. 12C). At least one contact layer 113 or 114 has embedded via extension patterns 115, which are filled with conductive material and have aspect ratio higher than 2×1. The high aspect ratio can be accomplished with small via size to accommodate the bond pads of the chip. Operation 103 cures the layers at a predetermined temperature. The insulating layers are solidified with certain degrees of shrinkage. The contact layers does not shrink, but converted to powder. Operation 104 removes the powdered contact layers, exposing the via extensions (FIG. 12D).

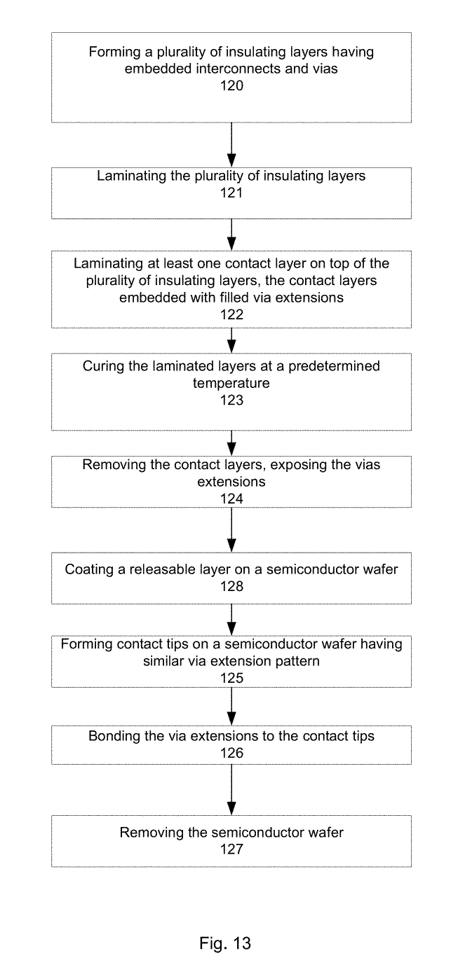

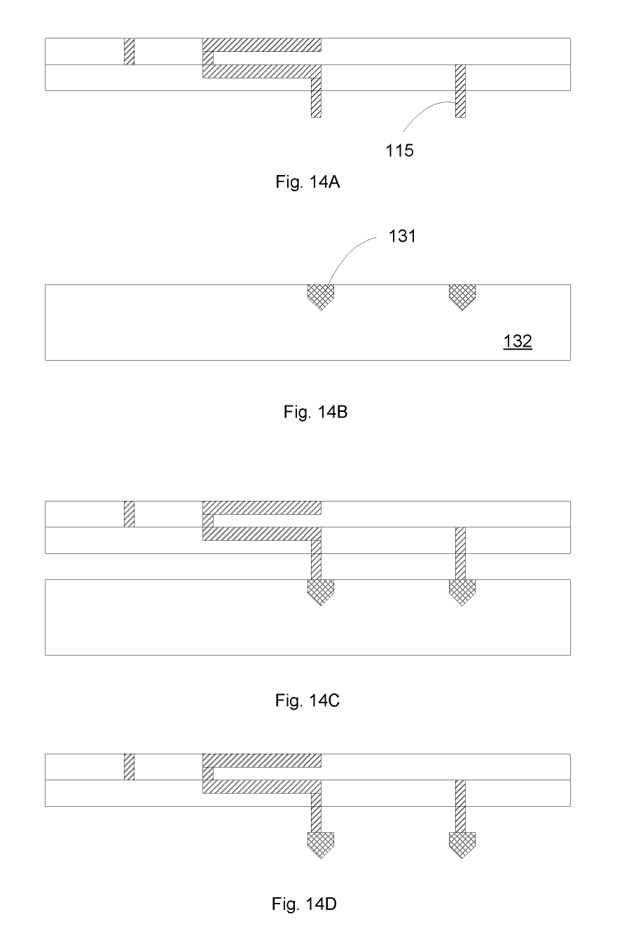

FIGS. 13 and 14A-14D illustrate an exemplary process flow for forming a contactor with contact tips fabricated from a semiconductor wafer. Operations 120-124 form the contactor with exposed via extension, wherein the contactor can have one or two contact layers with filled via extensions 115 (FIG. 14A). The aspect ratio of the filled via extensions is preferably higher than 2×1, but in general can be any value. Operation 125 forms contact tips on a semiconductor wafer 132 with similar via extension patterns 131. The contact tips can be formed in a layer 133 on top of the semiconductor wafer 132 (FIG. 14B). The planarity of the contact tips is thus determined by the flatness of the semiconductor wafer, allowing an accuracy in planarity of the contactor suitable for semiconductor device testing. The process of the contact tips can be performed by semiconductor processing, thus provides lateral dimensions, and lateral accuracy, of semiconductor processing, similar to that of the bond pads of semiconductor devices. Operation 126 bonds the via extensions 115 to the contact tips 131 (FIG. 14C). The bonding can be performed by soldering, with potential mis-alignment correction as discussed above. Operation 127 removes the semiconductor wafer from the contactor, forming a contactor having contact tips with planarity and lateral accuracy of semiconductor processing (FIG. 14D), suitable for matching the bond pads of semiconductor devices in testing.

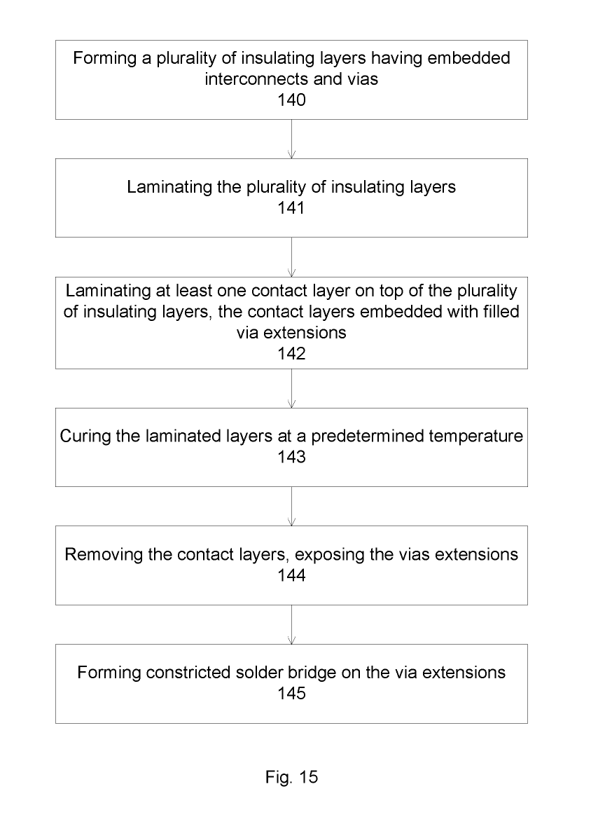

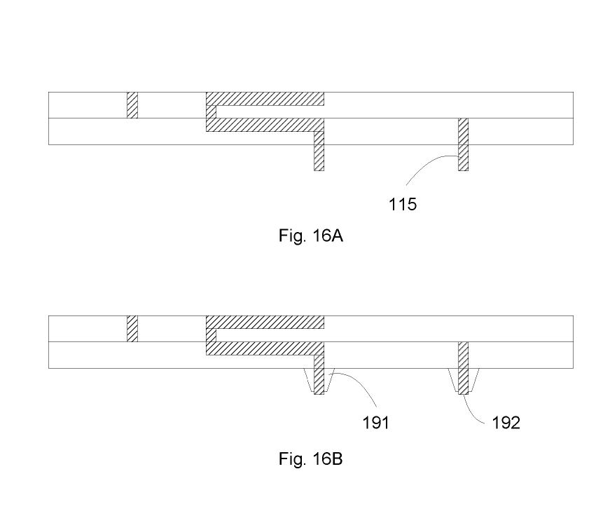

FIGS. 15 and 16A-16B illustrate an exemplary process flow for forming a contactor with constricted solder bridge. Operations 140-144 form the contactor with exposed via extension, wherein the contactor can have one or two contact layers with filled via extensions 115 (FIG. 16A). The aspect ratio of the filled via extensions is preferably higher than 2×1, but in general can be any value. Operation 145 forms a constricted solder bridge 191 on the via extension 115 (FIG. 16B). In an aspect, the constricted solder bridge 191 limits the soldering surface of the via extension 115, for example, protecting the side surfaces from being soldering, and allowing only the top surface 192 to be soldered.

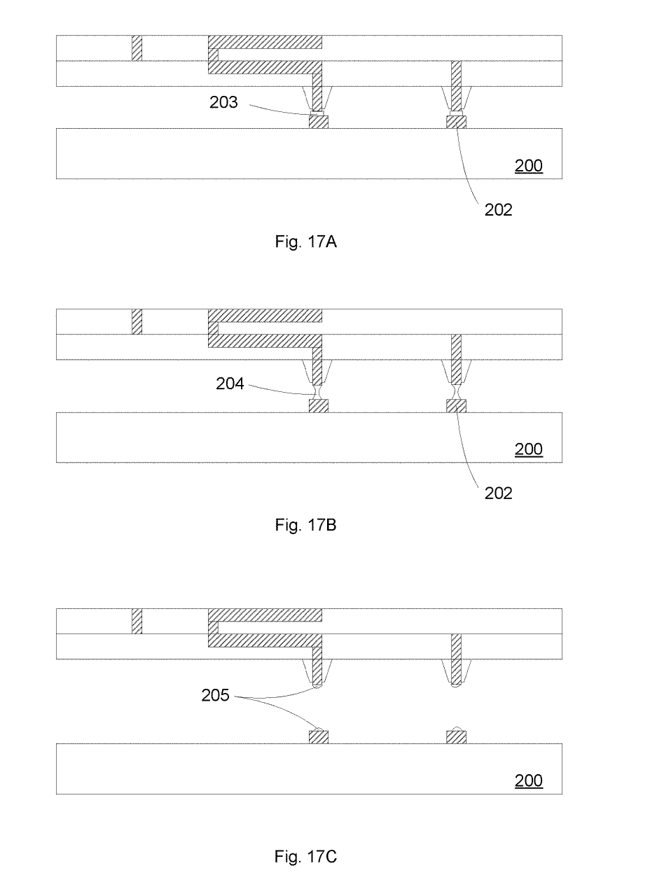

FIGS. 17A-17C illustrate an exemplary rework process for bonding a contactor with constricted solder bridge to a temporary substrate. The substrate 200 (for example, a semiconductor chip) has bond pads 202 for accessing internal devices. A contactor is bonded to the bond pads with solder 203 bonding with the constricted solder bridge (FIG. 17A).

After finish testing the chip, the contactor is removed. Under heated environment, such as heating the contactor, the solder is reflow and the contactor can be pulling out of the chip. Since the bonding between the via extensions and the bond pads is restricted, the solder 204 (FIG. 17B) can be broken off, and separated into residues 205 (FIG. 17C).

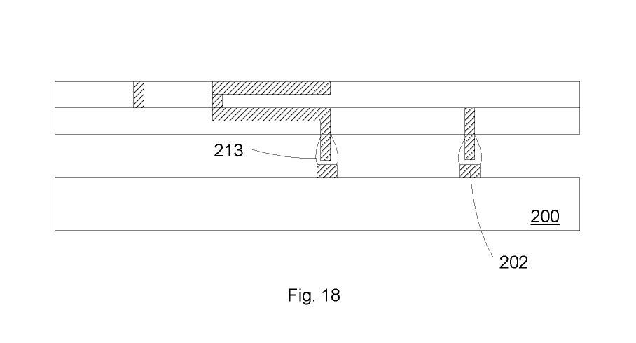

FIG. 18 illustrates an exemplary bonding for un-constricted via extensions. Without the constricted solder bridge, the solder can bond 213 to the top and side surfaces of the via extensions, forming a permanent bonding between the bond pads 202 of the chip 200 with the contactor.

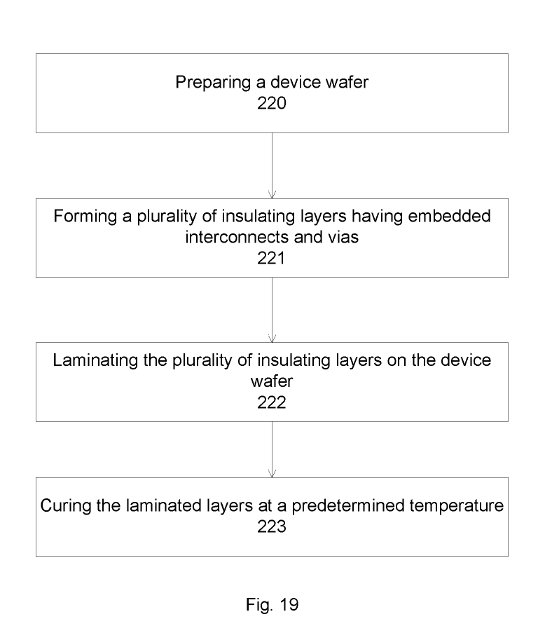

FIG. 19 illustrates an exemplary embodiment of the present integrated contactor on semiconductor wafer. Operation 220 prepares a semiconductor wafer, for example, with devices and inter connections. Operation 221 forms a plurality of insulating layers with embedded interconnects and vias. Operation 222 laminates a plurality of insulating layers on the device wafer, and operation 223 cures the laminated layers and the wafer at a predetermined temperature. This process forms an integrated wafer package, complete with a contactor on a semiconductor wafer. The wafer can then be tested and/or diced into individual chips.

What is claimed is:

1. A method to form a contactor, comprising:
forming a body,
wherein the body comprises a first substrate having a first surface,
wherein the body comprises a plurality of probes,
wherein the plurality of probes protrude above the first surface,
forming a plurality of terminals on a second substrate,
bonding the plurality of probes to the plurality of terminals;
encapsulating at least a portion of the plurality of the terminals, the bond between the plurality of probes to the plurality of terminals, and the plurality of probes; and
separating the plurality of terminals from the second substrate and from each other,
wherein separating the plurality of terminals from each other comprises having each terminal not directly or indirectly touches another terminal.

2. A method as in claim 1 further comprising
testing a device by contacting the plurality of terminals with terminal pads of the device.

3. A method as in claim 1 further comprising:
coating the second substrate with a releasable layer before forming the plurality of terminals,
wherein separating the plurality of terminals from the second substrate comprises releasing the releasable layer.

4. A method as in claim 1
wherein the releasable layer comprises an aluminum material,
wherein the second substrate comprises a semiconductor wafer,
wherein the plurality of terminals comprises a nickel material.

5. A method as in claim 1 wherein forming the terminals on the second substrate comprises
forming a pattern on the second substrate, wherein the pattern comprises recesses;
depositing a conductive material in the recesses to form the plurality of terminals.

6. A method as in claim 1 wherein forming the plurality of terminals on the second substrate comprises
forming an aluminum layer on the second substrate;
forming the plurality of terminals on the aluminum layer, wherein the plurality of terminals comprise a nickel material.

7. A method as in claim 1
wherein the plurality of terminals are formed by
forming dimples on the second substrate, wherein the dimples comprise recesses with tips in the surface of the second substrate;
filling the dimples with a metal paste and;
densifying the metal paste.

8. A method as in claim 1
wherein a planarity variation formed by the plurality of terminals is less than a planarity variation formed by the plurality of probes.

9. A method as in claim 7
wherein the planarity variation formed by the plurality of probes is characterized as a difference between at least a probe of the plurality of probes and a first plane formed by at least three probes of the plurality of probes,
wherein the planarity variation formed by the plurality of terminals is characterized as a difference between at least a terminal of the plurality of terminals and a second plane formed by at least three terminals of the plurality of terminals.

10. A method to form a contactor, comprising:
forming a body,
wherein the body comprises a first substrate having a first surface,
wherein the body comprises a plurality of probes,
wherein the plurality of probes comprise a plurality of probe tips protruded above the first surface,
wherein at least three probe tips of the plurality of probe tips form a first plane,
wherein the plurality of probe tips comprise a first planarity variation from the first plane;
forming a plurality of terminals on a second substrate,
wherein the plurality of terminals comprise a plurality of terminal surfaces exposed to external ambient,
wherein at least three terminal surfaces of the plurality of terminal surfaces form a second plane,
wherein the plurality of terminal surfaces comprises a second planarity variation from the second plane,
wherein the second planarity variation is less than the first planarity variation;
bonding the plurality of probes to the plurality of terminals;
encapsulating at least a portion of the plurality of the terminals, the bond between the plurality of probes to the plurality of terminals, and the plurality of probes; and
separating the plurality of terminals from the second substrate.

11. A method as in claim 10 further comprising:
coating the second substrate with a releasable layer before forming the plurality of terminals,
wherein separating the plurality of terminals from the second substrate comprises releasing the releasable layer,
wherein the releasable layer comprises an aluminum material,
wherein the second substrate comprises a semiconductor wafer,
wherein the plurality of terminals comprises a nickel material.

12. A method as in claim 10 wherein forming the plurality of terminals on the second substrate comprises
forming an aluminum layer on the second substrate;
forming the plurality of terminals on the aluminum layer, wherein the plurality of terminals comprise a nickel material.

13. A method as in claim 10
wherein separating the plurality of terminals from the second substrate further separates the plurality of terminals from each other, wherein separating the plurality of terminals from each other comprises having each terminal not directly or indirectly touches another terminal.

14. A method as in claim 10
wherein the first planarity variation formed by the plurality of probes is characterized as a difference between at least a probe of the plurality of probes and the first plane,
wherein the second planarity variation formed by the plurality of terminals is characterized as a difference between at least a terminal of the plurality of terminals and the second plane.

15. A method as in claim 10
wherein the first planarity variation formed by the plurality of probes is characterized as a maximum difference or an average difference between a probe of the plurality of probes and the first plane,
wherein the second planarity variation formed by the plurality of terminals is characterized as a maximum difference or an average difference between a terminal of the plurality of terminals and the second plane.

16. A method to form a contactor, comprising:
forming multiple bodies,
wherein each body comprises a first substrate having a first surface,
wherein the each body comprises a plurality of probes,
wherein the plurality of probes protrude above the first surface;
forming a plurality of terminals on a second substrate;
coupling the multiple bodies to the second substrate, wherein the coupling comprises bonding the plurality of probes of the multiple bodies to the plurality of terminals;
encapsulating at least a portion of the plurality of the terminals, the bond between the plurality of probes to the plurality of terminals, and the plurality of probes; and
separating the plurality of terminals from the second substrate,
wherein a planarity variation formed by the plurality of terminals is less than a planarity variation formed by the plurality of probes of the multiple bodies.

17. A method as in claim 16
wherein forming a plurality of terminals on a second substrate comprises
forming a first layer on the second substrate,
depositing a second layer of a conductive material on the first layer to form the plurality of terminals.

18. A method as in claim 16 wherein forming the plurality of terminals on the second substrate comprises
forming an aluminum layer on the second substrate;
forming the plurality of terminals on the aluminum layer, wherein the plurality of terminals comprise a nickel material.

19. A method as in claim 16
wherein separating the plurality of terminals from the second substrate further separates the plurality of terminals from each other, wherein separating the plurality of terminals from each other comprises having each terminal not directly or indirectly touches another terminal.

20. A method as in claim 16
wherein the planarity variation formed by the plurality of probes of the multiple bodies is characterized as a difference, a maximum difference, or an average difference between at least a probe of the plurality of probes of the multiple bodies and a first plane formed by at least three probes of the plurality of probes of the multiple bodies,
wherein the planarity variation formed by the plurality of terminals is characterized as a difference, a maximum difference, or an average difference between at least a terminal of the plurality of terminals and a second plane formed by at least three terminals of the plurality of terminals.
